(19) United States
(12) Patent Application Publication
(10) Pub. No.: US 2002/0142549 A1
(43) Pub. Date: Oct. 3, 2002

(54) Method for manufacturing a semiconductor device

(75) Inventor: Kiyotaka Miwa, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/102,686

(22) Filed: Mar. 22, 2002

(30) Foreign Application Priority Data
Mar. 27, 2001 (JP) 2001-088998

(51) Int. Cl. H01L 21/336

(52) U.S. Cl. 438/296

(57) ABSTRACT

The invention provides a method for manufacturing a semiconductor device, reducing the number of processes in a self-alignment metal damascene gate process. The invention deposits a silicon nitride film on a semiconductor substrate, selectively removes the silicon nitride film and the semiconductor substrate to form a trench groove, and deposits a first insulating film all over the semiconductor substrate so as to fill up the trench groove with it. Following this, the invention removes this first insulating film to expose said silicon nitride film and selectively removes the exposed silicon nitride film to form a dummy gate electrode.

### BACKGROUND OF THE INVENTION

1. Field of the Invention

The present invention relates to a method for manufacturing a semiconductor device, and more particularly to a method for manufacturing a semiconductor device formed by a damascene gate process.

2. Description of the Related Art

In recent years, in order to make a transistor more high-performance, a request for scaling down a device is increasing. Thus, a thermal oxide film as a gate insulating film is tending thinner in order to raise its dielectric constant. It has been studied to substitute a metal material of a low resistivity for the polysilicon, since polysilicon as a conventional material for a gate electrode have high resistivity.

However, a recent gate oxide film is made as thin as about 2.0 nm, and making it further thinner may cause a failure due to a gate oxide film leakage or a boron penetration. And since a metal material of a low resistivity as a gate electrode material is inferior in thermal resistance, it is not possible to apply a conventional manufacturing method of forming a gate oxide film and a gate electrode, and thereafter performing a high-temperature heat treatment on a source and drain.

In order to solve these disadvantages, therefore, a damascene gate process which adopts a high-dielectric constant film being substituted for a thermal oxide film, and forms a gate electrode after a high-temperature heat treatment has been performed has been proposed.

Such methods of this technique are described in Japanese Patent Laid-Open Publication No. Hei 11-243,150 and Japanese Patent Laid-Open Publication No.2000-315,789. These techniques form a gate electrode and a source and drain and then remove once the polysilicon gate electrode and thereafter bury again a gate electrode, whereby they form a transistor.

This is explained with reference to FIGS. 1A to 1H being schematic sectional views in the above-mentioned manufacturing processes.

First, as shown in FIG. 1A, a first silicon oxide film 501 is formed on a semiconductor substrate 500 using a thermal oxidation method. Following this, a silicon nitride film 502 is deposited using a CVD method. A photoresist 503 is applied onto this silicon nitride film 502 and is exposed and developed to form a specified pattern.

Next, as shown in FIG. 1B, a groove 504 for device isolation is formed by etching away the silicon nitride film 502, the silicon oxide film 501 and the semiconductor substrate 500 by about 200 nm by means of a dry etching method using the photoresist 503 as a mask. And the photoresist 503 is ashed and then stripped off.

Next, as shown in FIG. 1C, a silicon-based insulating film 505 is deposited by means of a CVD method at least until the groove 504 is completely filled up with it. After this, a first planarization process is performed by a CMP method, using a silicon nitride film 502a as a stopper.

Next, as shown in FIG. 1D, the silicon nitride film 502a is selectively etched away by a dry etching method or a wet etching method. Further, an insulating film 505a filling up the groove 504 is etched away and planarized to the same level as the semiconductor substrate 500 by means of a wet etching method.

And a second silicon oxide film 506 is formed on the silicon substrate 500 by means of a thermal oxidation method. A polysilicon 507 and a silicon nitride film 508 are-deposited on the silicon oxide film 506 by a CVD method, and a photoresist 509 is applied thereto, and thereafter is exposed and developed to form a gate electrode pattern. After this, an etching process is performed with a sufficient selection ratio relative to the silicon oxide film 506 by means of a dry etching method using the photoresist 509 as a mask to form a dummy gate electrode 510.

Next, as shown in FIG. 1E, an impurity is injected by means of an ion implantation method to form an extension 511 in a self-alignment manner. And a silicon oxide-based insulating film 512 is deposited by a CVD method and this silicon oxide-based insulating film 512 is etched back by a dry etching method to form a side wall 512a of an insulating film on a side wall of the dummy gate electrode 510 of polysilicon. Further, an impurity is injected by an ion implantation method to form a source and drain 513 in a self-alignment manner. After this, Co is deposited using a CVD method or a sputtering method and then a silicide 514 is formed on the semiconductor substrate 500 by a heat treatment using a rapid thermal annealing (RTA) method. Following this, the Co on the surface of the silicon oxide-based insulating film and silicon nitride film 508 is removed by an HPM solution.

Next, as shown in FIG. 1F, a silicon oxide-based insulating film 515 is deposited by means of a CVD method until the dummy gate electrode 510 is completely filled up with it. And a second planarization is performed by means of a CMP method until the surface of the dummy gate electrode 510 is exposed.

Next, as shown in FIG. 1G, the silicon nitride film 508 is etched away using a hot phosphoric acid solution. Further, the polysilicon 507 as a dummy gate electrode is etched away with a sufficient selection ratio relative to the silicon insulating film 506 by means of a dry etching method using a fluorocarbon-based gas for example. After this, the silicon oxide film 506 is etched away by an HF solution to form an opening.

Next, as shown in FIG. 1H, a high-dielectric constant insulating film 516 such as Ta205 for example is deposited on the surface of the silicon oxide-based insulating film 515 and the inner wall of the opening by means of a CVD method or a sputtering method, After this, a metal material 517 such as W or Al for example is deposited so as to fill up the opening with it by means of a CVD method or a sputtering method. Next, a third planarization is performed by means of a CMP method until the pattern of a gate electrode is exposed.

In such a way, after a heat treatment for activating an extension and a source and drain, a high-dielectric constant film and metal electrode is formed.

However, the prior art as described above needs to remove a portion of an insulating film, which uses for device isolation, projecting from a trench groove and to match the oxide film with a semiconductor substrate in height in order to prevent a lowering of the resolution in patterning a dummy gate electrode. Therefore, when a silicon oxide film 505 is etched away, an insulating film buried in the trench groove also is etched out to cause a shallow trench isolation (STI) divot.

Further, a protective film needs to be formed on a dummy gate electrode so that a silicide is not formed. Because, as described above, polysilicon to become a dummy gate electrode is etched by a fluorocarbon-based gas, but when silicide has been formed on the surface of polysilicon it is difficult to etch it. Therefore, a process of forming a nitride film on a polysilicon to become a dummy gate electrode so that a silicide is not formed, a process of removing it, and a process of removing a dummy polysilicon, and depositing and planarizing a high-permittivity insulating film and a metal electrode need to be added and as a result the number of processes is increased.

And there is a problem that when the polysilicon being a dummy gate electrode is etched away by a dry etching method, a crystal defect induced in a channel domain by introducing an etching gas deteriorates a transistor in characteristic.

A technique of using a silicon nitride film as a material for a dummy gate electrode is disclosed in Japanese Patent Laid-Open Publication No.2000-223,704, but it does not prevent a disadvantage caused by an STI divot.

### SUMMARY OF THE INVENTION

A main object of the present invention is to provide a method for manufacturing a semiconductor device reducing the number of processes in a self-alignment metal damascene gate process.

Another object of the present invention is to provide a manufacturing process improving the process margin of a CMP process for exposing a dummy gate electrode and capable of providing a well-shaped gate electrode.

A further other object of the present invention is to provide a transistor manufacturing process of suppressing the induction of a crystal defect in a gate channel by using a wet etching method instead of a dry etching method in order to remove a dummy gate electrode.

A still further other object of the present invention is to provide a semiconductor device manufacturing method of preventing a shallow trench isolation divot from being formed.

A method for manufacturing a-semiconductor device according to the present invention comprises forming a silicon nitride film on a semiconductor substrate; selectively removing the silicon nitride film and the semiconductor substrate to form a trench groove; forming a first insulating film in the trench groove and on the semiconductor substrate so as to bury the trench groove; removing the first insulating film to expose the silicon nitride film; and selectively removing the exposed silicon nitride film to form a dummy gate electrode.

That is to say, this method forms a dummy gate electrode out of a silicon nitride film used as a stopper when filling up a trench groove with an insulating film. Although a device isolation insulating film and a semiconductor substrate must have been matched in level with each other in order to improve the resolution in patterning of a dummy gate electrode, this process can be omitted by forming a dummy gate electrode out of a silicon nitride film described above.

A dummy gate electrode composed of the above silicon nitride film eliminates the need for forming a protective film on the dummy gate electrode in a process of forming a silicide on a source and drain. Further, since it is possible to polish an interlayer dielectric film using the dummy gate electrode as a stopper in a process of providing the interlayer dielectric film, a well-shaped gate electrode can be formed. And since a dummy gate electrode can be removed by a wet etching method, it is not necessary to use a dry etching method which may damage a channel.

### BRIEF DESCRIPTION OF THE DRAWINGS

The above and other objects, advantages and features of the present invention will be more apparent from the following description taken in conjunction with the accompanying drawings, in which:

FIGS. 1A to 1H are schematic sectional process diagrams showing a method for a semiconductor device of the prior art; and

FIGS. 2A to 2I are schematic sectional process diagrams showing a method for a semiconductor device of the present invention.

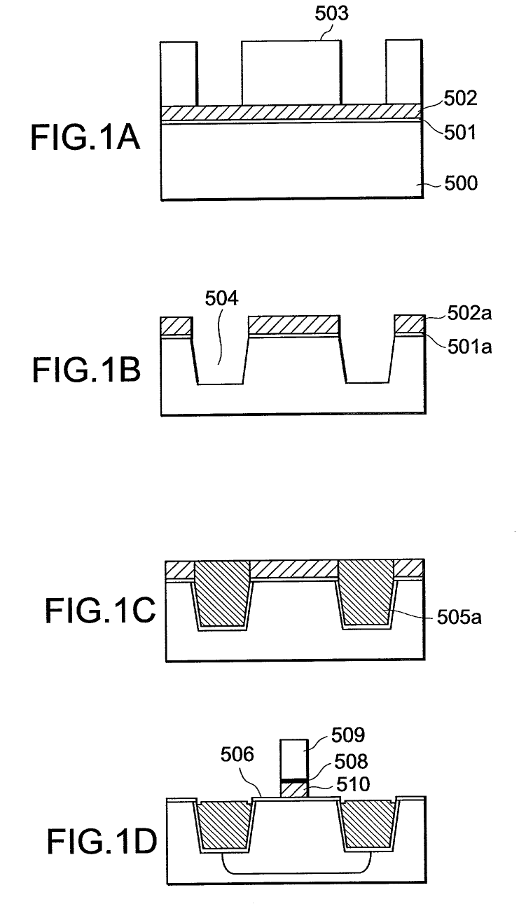

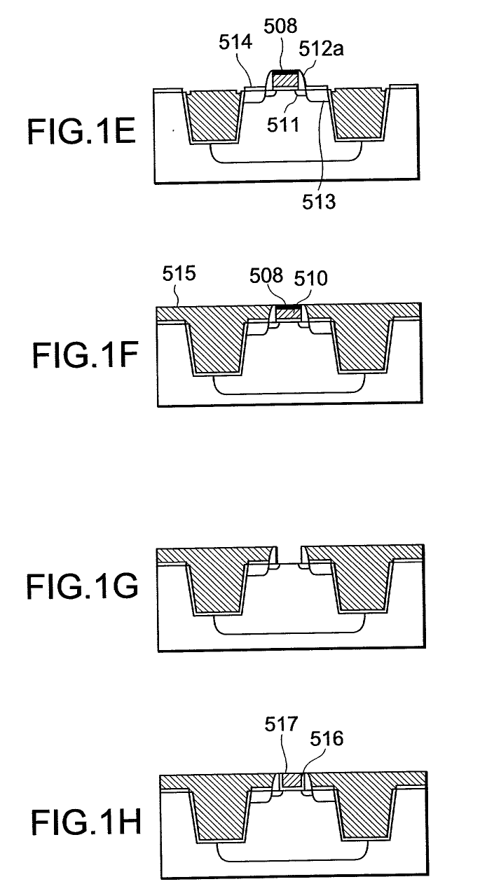

### DETAILED DESCRIPTION OF THE PREFERRED EMBODIMENTS

An embodiment of the present invention is described with reference to the drawings.

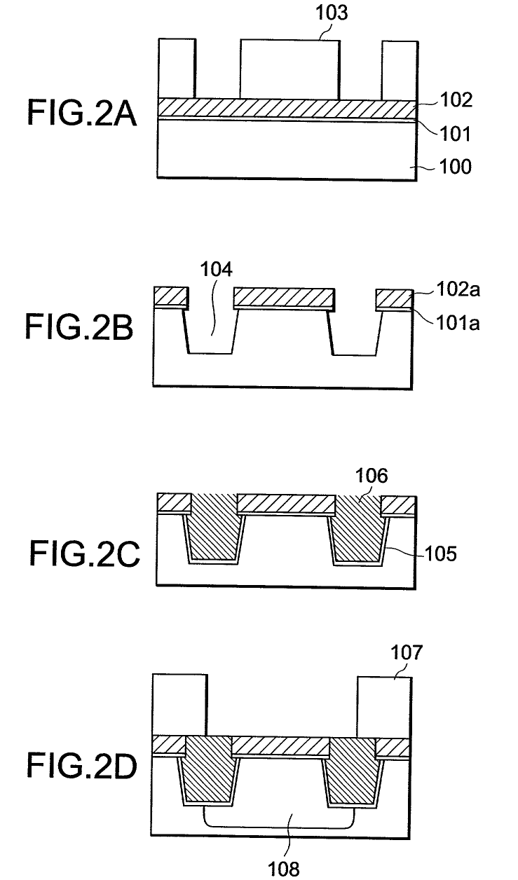

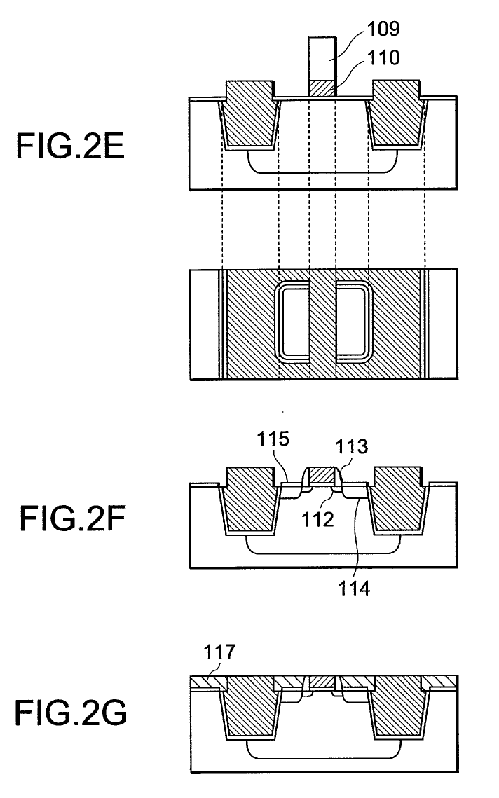

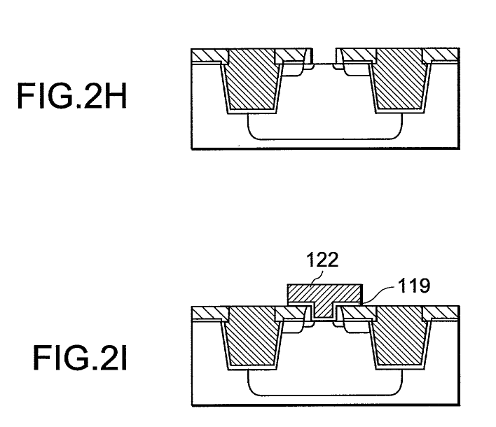

First, as shown in FIG. 2A, a silicon oxide film 101 of about 8 to 16 nm is formed on a semiconductor substrate 100 by means of a thermal oxidation method, and then a silicon nitride film 102 is deposited to about 50 to 200 nm. The silicon oxide film 101 has a role of relaxing a film stress of the silicon nitride film 102 and a role of protecting an active region of the semiconductor substrate 100 from a hot phosphoric acid solution used in removing a nitride film. On the other hand, the silicon nitride film 102 has a role as a stopper in polishing by a CMP method. The thickness of the silicon nitride film 102, which is optimized by the combination of exposure wavelength and photoresist 103, ranges from 50 to 200 nm. Subsequently to this, a photoresist 103 is applied, and is exposed and developed to form a desired pattern.

Next, as shown in FIG. 2B, an anisotropic etching process is applied to the silicon nitride film 102 and then the silicon oxide film 101 in order in an opening of the photoresist 103. Due to this process, a photoresist pattern is transferred to the silicon nitride film 102 and the silicon oxide film 101 to form a silicon nitride film 102a and a silicon oxide film 101a, respectively. After this, a trench groove 104 is formed by etching the semiconductor substrate 100 in the opening by about 200 to 400 nm by means of a dry etching method using the photoresist 103 or the silicon nitride film 102a as a mask.

At this time, for the purpose of enhancing the electric isolation margin of a source and drain, it is preferable to etch the semiconductor substrate 100 so as to spread outside by about 0.02 μm in relation to the opening of the photoresist or the silicon nitride film 102a. In case of obtaining a desired characteristic without doing as described above, it is not necessary to take such a structure in particular. As an etching gas, Cl₂O₂ is used and a tapered gas ratio of about 80 to 85 degrees is selected in order to improve the electric characteristics. And HBr may be added for the purpose of improving the electric characteristics.

Next, as shown in FIG. 2C, a thermal oxide film 105 of about 10 to 40 nm is formed in a trench groove 104 by means of a thermal oxidation method for the purpose of improving the electric characteristics of device isolation. Then, the trench groove 104 is filled up with a bias oxide film or coating-type oxide film 106 as a device isolation insulating film, and a first planarization process is performed using the nitride film 102a as a stopper by means of a CMP method.

Next, as shown in FIG. 2D, a photoresist 107 is applied, and is exposed and developed to form an N-well or P-well pattern. N well or P well 108 is formed by injecting impurity ions so as to penetrate the silicon nitride film 102a and the silicon oxide film 110a and be distributed to a depth of 0.5 to 1 μm of the semiconductor substrate 100 by ion implantation method using the photoresist 107 as a mask.

Next, a photoresist 109 is formed, and exposed and developed to form a gate electrode pattern. After this, as shown in FIG. 2E, the silicon nitride film 102a is anisotropic-etched by means of a dry etching method using the photoresist 109 as a mask with a sufficient selection ratio to the silicon oxide film 110a and the bias oxide film or coating-type oxide film 105. At this time, a CF-based gas is used as an etching gas, but the etching gas is not limited to this but any etching gas capable of giving a desired shape can be used.

After this, the photoresist 109 is removed, and a dummy gate electrode 110 of a silicon nitride film 102a is formed.

A gate electrode is formed larger than a channel width in consideration of variation in process. In the present invention, as seen the bottom of the FIG. 2E which shows the top view of the top of FIG. 2E, since the trench groove is formed larger than an opening of the silicon nitride film. As a result, the silicon nitride film 102a remains to be larger than the channel width. Therefore, a gate electrode larger than the channel width can be easily formed by using this silicon nitride film 102a as a dummy gate electrode.

And since a dummy gate electrode is formed using a silicon nitride film as a stopper, it is not necessary to allow for a level difference on the surface to be exposed when exposing a dummy gate electrode pattern to light. In short, a surface planarization process for exposing a dummy gate electrode pattern to light is made unnecessary differently from the prior art. Thus, a problem is eliminated that a level difference (shallow trench isolation divot) is formed at a peripheral edge of an oxide film projecting from a trench groove.

Next, a photoresist is applied, and is exposed and developed to form an N-well or P-well pattern. And as shown in FIG. 2F, impurity ions are injected to form an extension 112 by means of an ion implantation method using the photoresist and the dummy gate electrode 110 as a mask. Further, after a silicon oxide film is deposited by about 5 to 20 nm by means of a CVD method, the silicon oxide film is anisotropic-etched by a dry etching method to form a silicon oxide film wall 113 of about 5 to 20 nm on a side wall of the dummy gate electrode 110. And impurity ions are injected by means of an ion implantation method using the dummy gate electrode 110 and the silicon oxide film wall 113 as a mask to form a source and drain 114 in a self-alignment manner, and the photoresist 111 is ashed and then cleaned away.

After this, an activating heat treatment is applied to the extension 112 and the source and drain 114 by means of a rapid thermal annealing (RTA) method for example.

Next, Co is deposited by means of a CVD method or a sputtering method, and is heat-treated by means of an RTA method to form a silicide only on the semiconductor substrate 100. And the Co on the dummy gate electrode 110 formed out of a bias oxide film or coating-type oxide film 105 and a silicon nitride film is removed by an HPM solution and a silicide 115 is formed only on the source and drain 114.

Subsequently to this, as shown in FIG. 2G, in order to protect the dummy gate electrode 110, the silicon oxide film wall 113 and the silicide 115, a silicon oxide film 116 is formed to about 10 to 20 nm by means of a CVD method. And a bias oxide film or coating-type oxide film 117 is deposited so that the dummy gate electrode 110 is sufficiently buried, and a second planarization process is performed by means of a CMP method until the dummy gate electrode 110 is exposed. At this time, the dummy gate electrode 110 formed out of a silicon nitride film performs a role as a stopper of the CMP and bears a part in providing a stable polishing characteristic.

Next, as shown in FIG. 2H, the silicon nitride film of the dummy gate electrode 110 is removed by a hot phosphoric acid solution. The silicon nitride film of the dummy gate electrode 110 is anisotropically etched away nearly to half by a dry etching method with a sufficient selection ratio to the bias oxide films or coating-type oxide films 106 and 117 on the device isolation region and the source and drain, and to the silicon oxide film wall 113 of the dummy gate electrode. Further, the silicon nitride film may be removed by a hot phosphoric acid solution.

Next, a photoresist is applied, and is exposed and developed to form such a pattern that a channel portion is opened. And impurity ions for adjusting the threshold value of a transistor is injected directly under the gate electrode in a self-alignment manner by means of an ion implantation method using the photoresist, the bias oxide film or coating-type oxide film 117 and the silicon oxide film wall 113 as a mask.

Next, the photoresist is stripped off and the thermal oxide film 110a remaining in the lower part of the gate groove after the dummy gate electrode 110 has been removed is removed by a dilute HF solution.

Next, as shown in FIG. 2I, a high-permittivity insulating film 119 is deposited to about 10 to 20 nm by means of a CVD method or a sputtering method. As a material for this, for example, Ta₂O₅ is used but the material is not limited to this and any material capable of providing a desired characteristic may be used. And a metal film 120 is deposited by means of a CVD method or a sputtering method so as to fill up the gate groove with it, said groove remaining after the dummy gate electrode has been removed. As a material for this, for example, Al or W is used but the material is not limited to these and any material capable of providing a desired characteristic may be used.

Next, a photoresist is applied, and is exposed and developed to form a desired wiring pattern, and the metal film 120 and the high-permittivity insulating film deposited on the bias oxide film or coating-type oxide film 117 are removed by means of a dry etching method using the photoresist as a mask. Further, the wiring pattern of the photoresist 121 is transferred to form the wiring 122 connecting metal gate electrodes.

According to the above-mentioned process, by forming a dummy gate electrode 110 out of a silicon nitride film used as a stopper in a CMP process at the time of filling up a trench groove with an insulating film, it is possible to eliminate a process of matching a device isolation insulating film with a semiconductor substrate in height, a process of forming a silicon thermal oxide film before depositing polysilicon, and a process of depositing polysilicon.

And since a dummy gate electrode 110 is formed out of a silicon nitride film, it is not necessary to deposit a protective film on the dummy gate electrode in order to form a silicide in a source and drain region 114.

Furthermore, in a process of performing a planarization process so as to expose a dummy gate electrode on which a bias oxide film or coating-type oxide film 117 as an interlayer insulating film has been deposited, since the dummy gate electrode 110 is formed out of a silicon nitride film, it is possible to perform a planarization process with a sufficient selection ratio and as a result, form a well-shaped gate electrode.

Moreover, since a dummy gate electrode 110 is removed :by a wet etching method using a hot phosphoric acid solution, it is possible to prevent such degradation in performance that an etching damage caused by dry etching influences a channel and increases a leakage current of a transistor, and the like.

Application examples of the present embodiment are not limited to the above description in composition materials and various numerical values.

It is apparent that the present invention is not limited to the above embodiments, but may be modified and changed without departing from the scope and spirit of the invention.

What is claimed is:

1. A method for manufacturing a semiconductor device, comprising;
forming a silicon nitride film on a semiconductor substrate;
selectively removing said silicon nitride film and said semiconductor substrate to form a trench groove;
forming a first insulating film in said trench groove and on said semiconductor substrate so as to bury said trench groove;
removing said first insulating film to expose said silicon nitride film; and
selectively removing said exposed silicon nitride film to form a dummy gate electrode.

2. A method for manufacturing a semiconductor device according to claim 1, further comprising;
covering a second insulating film on said dummy gate electrode, said semiconductor substrate and said first insulating film;
removing said second insulating film to expose the top surface of said dummy gate electrode;
removing said exposed dummy gate electrode to form an opening;
forming a gate insulating film at least on the bottom of said opening; and
filling up said opening with a gate electrode after forming said gate insulating film.

3. A method for manufacturing a semiconductor device according to claim 2, wherein said gate insulating film have a high dielectric constant.

4. A method for manufacturing a semiconductor device according to claim 2, wherein said gate electrode is of metal.

5. A method for manufacturing a semiconductor device according to claim 1, wherein said first insulating film is formed projecting higher from the surface of said semiconductor substrate.

6. A method for manufacturing a semiconductor device according to claim 1, wherein said silicon nitride film is exposed by a CMP process of polishing said first insulating film using said silicon nitride film as a stopper.

7. A method for manufacturing a semiconductor device according to claim 1, further comprising;
forming a source and drain in a self-alignment manner using said dummy gate electrode as a mask; and
forming a silicide on said semiconductor substrate.

8. A method for manufacturing a semiconductor device according to claim 1, wherein;
said trench groove is larger than said opening of the silicon nitride film.

9. A method for manufacturing a semiconductor device according to claim 2, wherein said dummy gate electrode is removed by a wet etching method.

10. A method for manufacturing a semiconductor device according to claim 2, wherein said dummy gate electrode is removed by a wet etching method using a hot phosphoric acid solution.

11. A method for manufacturing a semiconductor device according to claim 2, wherein said the top surface of said dummy gate electrode is exposed by a CMP process of polishing said second insulating film using said dummy gate electrode as a stopper.
